(19) United States
(12) Patent Application Publication
(10) Pub. No.: US 2026/0332450 A1
(43) Pub. Date: Oct. 22, 2026

(54) SIGNAL PROCESSING DEVICE FOR A COMMUNICATION SYSTEM, AND METHOD FOR OPERATING A SIGNAL PROCESSING DEVICE OF THIS TYPE

(71) Applicant: AUDI AG, Ingolstadt (DE)

(72) Inventor: Bernhard SCHWANTNER, Eichstätt (DE)

(73) Assignee: AUDI AG, Ingolstadt (DE)

(21) Appl. No.: 19/107,751

(22) PCT Filed: Aug. 23, 2023
(86) PCT No.: PCT/EP2023/073846

§ 371 Date: Feb. 28, 2025

(30) Foreign Application Priority Data
Sep. 1, 2022 (DE) 10 2022 122 152.0

(51) Int. Cl. H04L 12/40; H03K 17/687

(52) U.S. Cl. CPC H04L 12/40143; H03K 17/687; H04L 2012/40273

(57) ABSTRACT

A signal processing device for a communication system, such as a BUS system. The signal processing device performs two different functions, depending on a drop in an energy supply signal (E): a communication function and an emergency operation function. In the case of the communication function, a communication-system-compliant control signal (S) is generated by the signal processing device for transfer as a message signal between a transmitting device coupled to the signal processing device and a receiving device. In contrast, in the case of the emergency operation function an activation signal (A) is generated for transfer as a supply signal between the transmitting device and the receiving device.

### CROSS REFERENCE TO RELATED APPLICATIONS

This application is a U.S. national stage of International Application No. PCT/EP2023/073846, filed on Aug. 30, 2023 which claims the priority benefit of German Application No. 10 2022 122 152.0, filed on Sep. 1, 2022. Both the International Application and the German Application are incorporated by reference herein in their entirety.

### BACKGROUND

### 1. Field

Disclosed herein is a signal processing device for a communication system and a method for operating a signal processing device. In addition, the disclosure also relates to a corresponding communication system and a transmitting device having a corresponding signal processing device. Finally, the disclosure also relates to an electrical network in which a corresponding signal processing device can be used.

### 2. Description of the Related Art

In an electrical network, for example an electrical system of a motor vehicle, it is possible for a communication system, for example a so-called BUS system, to be used to permit the transmission of data between individual subscribers or terminals in the network. The terminals may be, for example, a transmitting device, for example a central computing unit (ECU—Electronic Control Unit), and an associated receiving device, for example an actuator unit, for providing a specific function in the vehicle. In the context of control of a vehicle door, the transmitting device may be an electronic door controller (eTSG), for example, while the receiving device is an actuator unit for electric exterior handle operation (eTAB). The eTAB can have, for example, a servomotor as an actuator, for example in order to adjust or control a Bowden cable, which can be used to unlock or lock the vehicle door. For control, the eTSG can emit a control command, for example “lock door” or “unlock door”, and transmit it to the respective receiving device via the communication system.

In modern network architectures, there may be provision for a common controller to be able to control multiple, that is to say two or more, different receiving devices. Information or control commands is/are sent and/or received via a common transmission path, which is predefined by the topology of the communication system. The individual data transmissions should remain clearly separate from one another, however. To this end, the control command for the respective receiving device is encoded in a communication-system-compliant control signal when transmitted via the communication system. That is to say that a signal form and/or composition is matched to the chosen communication system, that is to say the communication standard thereof. Established communication standards in the automotive sector are LIN (Local Interconnect Network) and CAN (Controller Area Network), inter alia.

The communication system comprises a signal processing device for the encoding. Said signal processing device has, for example, a controller or a so-called transceiver that can be used to convert or translate the control command into the control signal. The controller requires electric power for operation, which can be delivered by a power supply unit of the relevant network.

In certain cases, for instance a vehicle accident or in the event of short-term overload, interruptions can occur in the power supply. The translation function of the controller can then no longer be guaranteed. This is a disadvantage for example when at least a basic operability of the receiving devices in the network should be maintained.

WO 2016/058815 A1 discloses, for example, the use of a LIN BUS, for example in order to be able to ensure essential basic functions of vehicle modules if the power supply is interrupted. In an energy-saving mode, this is accomplished by encoding sensor data differently than in a normal operating mode, for example.

DE 10 2014 207 993 A1 discloses, for example, a power transmission device for implementing a redundant power supply. It comprises two-channel supply of electric power that permits the energy to be reliably forwarded to a load.

A disadvantage of this is that an additional power supply line or emergency power line needs to be integrated into the network. This emergency power line is installed only for when there is a fall in the supply, for example a loss of power, and otherwise has no other function. The likelihood of such a use case occurring is very low, however. The additional line also gives rise to additional costs.

### SUMMARY

An aspect of the invention is directed to feature(s) to guarantee, on demand, for example in the event of a fall in a power supply, that a receiving device can be controlled by a transmitting device, and to reduce expenditure on additional costs.

A receiving device may be integrated into the signal processing device of the communication system on demand, for example to select a safe state of the receiving device.

That is to say that the signal processing device, in particular the lines thereof, is used to provide an emergency power supply line in the event of a loss of power. The emergency supply of power is delivered without utilizing the associated controller of the signal processing device. It is thus possible to ensure that the remaining energy in the network is sufficient to control the receiving device and is used up for operating the controller.

Specifically, this functionality is implemented, according to one aspect of the invention, by a signal processing device for a communication system. The signal processing device is, for example, an adapter circuit and/or connection circuit for connecting a transmitting device to the communication system. The communication system may, for example, be a so-called BUS system.

The signal processing device is designed to process, that is to say for example to transmit and generate, electrical signals that are able to be transmitted in an electrical network between at least one transmitting device and at least one associated receiving device by the communication system. The transmitting device and the receiving device are terminals or subscribers in the electrical network that, for example, can exchange, and therefore send or receive, control commands via the signal processing device. The two or more terminals are able to be interconnected or connected by the communication system to form the electrical network.

To permit signal transmission, the signal processing device comprises a respective transmitter connection for coupling to the respective transmitting device and a respective receiver connection for coupling to the respective receiving device. The receiver connection and the transmitter connection therefore form a signal output and a signal input of the signal processing device. The receiving device may, for example, be connected to the receiver connection via a data line of a signal line network of the communication system. By way of example, multiple transmitting or receiving devices may be connected via a common transmitter or receiver connection.

In addition, the signal processing device comprises a power supply connection for coupling to a power supply unit for supplying electric power for the electrical network. The power supply connection can be used by the signal processing device to receive or acquire a power supply signal that is generated or delivered by an energy supplier of the power supply unit for the electrical network. The power supply signal may, for example, be an operating voltage that is able to be tapped off between two reference-ground potentials of the power supply unit, for example a positive potential and a negative potential (ground potential).

The signal processing device also comprises a signal generation circuit having at least one signal generation controller. The signal generation controller, subsequently also called controller for short, is designed to encode a control command delivered by the respective transmitting device via the respective transmitter connection into a communication-system-compliant control signal and to deliver said signal on the receiver connection for the associated receiving device. The signal generation circuit, in particular the associated controller, can therefore be used to convert the control command into an information signal, for example for supply to the data line for transmission to the receiving device. The signal encoding can take place on the basis of a respective communication standard of the communication system. The signal encoding can take place using the electric power delivered in the form of a power supply signal on the power supply connection.

In order to provide the function of the receiving device being able to be controlled on demand, the signal processing device further comprises a bypass circuit. The bypass circuit is designed so as, in an activated state, to deliver a trigger signal, which is delivered by the transmitting device via the transmitter connection and differs in its signal type from the control signal, directly to the receiver connection by bypassing the signal generation circuit. To put it another way, the signal on the transmitter connection is connected to the receiver connection directly and without signal encoding based on the respective communication standard. The trigger signal is in particular not an information signal. It may instead be a supply signal, for example. In the activated state, the bypass circuit is connected in an electrically conducting or conductive manner, for example. The opposite is, for example, a deactivated state, in which the bypass circuit is connected in an electrically insulating or nonconductive manner.

The signal processing device comprises an activation circuit for activating or deactivating the bypass circuit. The activation circuit is designed to monitor the power supply signal, which is delivered by the power supply unit and is able to be tapped off from the power supply connection, in accordance with a predefined activation criterion. The activation circuit is designed to activate the bypass circuit on the basis of a monitoring result. In particular, activation of the bypass circuit deactivates the signal generation circuit. The activation circuit therefore provides a switching function between the signal generation circuit and the bypass circuit.

Depending on the state of the power supply, the trigger signal can therefore be delivered directly to the receiving device instead of the encoded control signal. The communication system can therefore be used, for example in an emergency, to directly supply power to the respective receiving device. This results in the advantage that no energy is consumed for supplying power to the signal generation controller when required. The energy can instead be transmitted directly to the receiving device, for example in order to take or put it into a specific state, for example a safe state. The trigger signal can therefore be used to trigger or select a predefined emergency state of the receiver device, for example. The emergency state may be, for example, deactivating or unlocking or another measure for taking the receiving device into the predefined safe state. Using the specific example of door unlocking for a vehicle, it is thus possible, for example, for a motor for a Bowden cable to be driven to unlock the vehicle door directly using the trigger signal (“cast out” Bowden cable) if the vehicle is, for example, involved in an accident in which the vehicle battery has been disconnected or damaged.

The signal processing device in the present instance is a component in the communication system for coupling multiple, that is to say two or more, terminals for signal or data transmission. Signal transmission can take place unidirectionally or bidirectionally, depending on the type of communication system selected, or on the type of associated communication standard. Signal transmission can comprise conveying a device setting, a device state, an error diagnosis or status information.

The signal processing device can, as described previously, transmit or deliver two different signals, or signal types: firstly the control signal and secondly the trigger signal.

The control signal is, in particular, an electrical signal of the information signal or data signal type. That is to say that the control signal is, in particular, not used to transmit power.

Instead, preferably only the control command, that is to say the message and/or information, is encoded in a desired signal form. The control signal is, in particular, a digital signal or binary signal known per se. That is to say that it is a signal that is modulated or composed from voltage pulses having a predetermined pulse pattern. The voltage pulses preferably only alternate between two discrete states or levels, specifically for example the “high” state and the “low” state. By way of example, the aforementioned positive potential of the power supply unit may be associated with the “high” state, while the “low” state has ground potential associated with it.

The control signal in the present instance is “communication-system-compliant”. That is to say that it encodes the control command in a signal form or a format that is permissible in the communication system. The control signal therefore complies with the regulations or standards for data transmission in the communication system. The signal form of the control signal can depend on the type of communication system. For example, the control signal may be formed in accordance with the so-called LIN standard if the communication system is the known LIN BUS.

By contrast, the trigger signal is preferably a signal of the driver signal or power (supply) signal type. That is to say that the trigger signal can operate or supply an actuator system of the receiver device with electric power. The trigger signal therefore does not need to be communication-system-compliant. It suffices if the trigger signal is receiving-device-compliant, that is to say able to be processed or implemented by the receiver. The trigger signal can be generated by the transmitting device or a component of the transmitting device, for example.

The trigger signal may, for example, comprise only or precisely a single signal pulse, in particular a short signal pulse of a few milliseconds. When the signal pulse is received by the receiving device, adoption of a predefined default or basic setting that is consistent with the emergency state can be triggered. The electric power for implementing the default setting is transmitted or transported by the trigger signal. By comparison, the control signal may be an AC signal having multiple successive signal pulses that are combined in a predetermined pulse pattern.

The signal generator circuit having the associated controller can be understood in the present instance as a translator between the control command and the control signal, for example. The controller implements the respective communication principle according to the type of communication system. That is to say that it adapts the signal form of the controller.

The signal form can comprise not only the pulse pattern but also, for example, a frequency, a level, a duty ratio and a message structure. The signal generator controller may be a microcontroller or microprocessor, for example. If the communication system provides for a so-called master-slave configuration, the controller may be a master controller. A driver circuit or control unit of the receiving device, on the other hand, may form a slave controller, for example.

The transmitting device may form, for example, a control device or an electronic computing unit (electronic control unit-ECU) for the associated receiving device(s). In particular, the transmitting device may be a central computing unit (central processing unit CPU), in the automotive sector a central onboard computer, for example.

The receiving device may be in the form of an actuator or actuator unit. The receiving device can comprise a control element or an actuator system. The control element may be a servomotor or a switch, for example. The driver circuit or the control unit of the receiving device may be designed to process the signal conveyed by the transmitting device. The driver circuit can decode the control command from the control signal, for example, in order to drive the control element therewith. Examples of a receiving device in the automotive sector are, inter alia, a window lifter, a door opener, or a windshield wiper or a lighting system. There may naturally also be provision for sensors or sensor units as a receiving device in the electrical network.

A transmitting device having multiple, that is to say two or more, receiving devices (or vice versa), for example, may be coupled in the electrical network by the communication system. The topology of the coupling can depend in particular on the chosen communication system type.

The bypass circuit comprises, for example, an electrical line that couples the first and second connections to one another. It may, by way of example, also comprise elements, in particular passive elements, such as a resistor or diode, for signal adaptation of the trigger signal. It is only important that the bypass circuit comprises no additional controller.

The activation circuit is designed to monitor the power supply by acquiring and evaluating the power supply signal in accordance with the aforementioned activation criterion.

How the monitoring can be implemented is described in more detail later on. The activation criterion comprises, for example, a rule and/or an algorithm that, when applied or performed, results in activation or deactivation of the bypass circuit being determined. The activation or deactivation is therefore determined by implementing the activation criterion.

The connections of the signal processing device can form in particular electrical contacts for electrically connecting or coupling to the terminals, or the power supply unit. The respective connection partner in the electrical network can comprise a complementary or corresponding connection for connecting to the respective connection of the signal processing device. The connections can collectively form a connection interface.

The invention also includes embodiments that result in additional advantages.

According to one embodiment, the activation circuit is designed to check, in accordance with the activation criterion, whether the power supply signal, in accordance with a check condition, has a response that is associated with the predefined emergency state of the electrical network, and the activation circuit is designed to activate the checking circuit if or in particular only when the check is positive. The trigger signal can therefore be delivered and the receiving device can be taken to the aforementioned default setting. If the check is negative, on the other hand, the bypass circuit remains or is deactivated. The control signal is then delivered.

In the present instance, a positive check that the power supply signal has the response associated with the emergency state. By contrast, a negative check signifies that the power supply signal has a different response than the one associated with the emergency state.

The association between the response and the emergency state may be stored in an association rule, for example. The association rule may be implemented as an association table or lookup table, for example.

The emergency state may be, for example, a state of the network in which the supply of power to the network can no longer be ensured or guaranteed. The emergency state can manifest itself, for example, as a fall in the power supply, that is to say, for example, a reduction in the supply voltage. The emergency state can therefore be seen or deduced from the power supply signal. The emergency state can arise when the network or a component of the network, such as the power supply unit or one of the terminals, has a malfunction or a fault. Alternatively, the emergency state may also exist when, for example, the power supply unit is shut down or deactivated. This occurs with battery-operated vehicles, for example, when the vehicle is involved in an accident or a vehicle battery, as energy supplier, overheats. It is then advantageous to unlock the vehicle door, for example, so that passengers can leave the crashed vehicle.

The aforementioned check condition comprises, for example, a rule and/or an algorithm that, when applied or performed, results in activation or deactivation of the bypass circuit being determined. The activation or deactivation is determined by implementing the check condition.

In the context of the check condition, there is provision in a further embodiment for the activation circuit to be designed to check, in accordance with the check condition, whether the power supply signal currently has a value that is below a predefined minimum limit value. The minimum limit value indicates that the emergency state exists. The activation circuit is designed to activate the bypass circuit if or in particular only when the check is positive. Otherwise, the bypass circuit remains or is deactivated, as described previously.

A limit value comparison can therefore be performed in order to ascertain whether or not the emergency state exists. The minimum limit value may be a limit value or threshold value that distinguishes a range of values, for the power supply signal, that is associated with the emergency state from a range of values that is not associated with the emergency state. The minimum limit value may be predefined by the energy requirements of the network. It can be determined by test trial or computed by simulation. In the case of a network with a rated voltage of 12 V, the minimum limit value may be 3 V, for example. A different minimum limit value of 5 V or 9 V, for example, is naturally also conceivable.

In the present instance, a positive check means that the value of the power supply signal is below the minimum limit value. A negative check, on the other hand, means that this signal value is above the minimum limit value or corresponds to said minimum limit value, for example.

The activation circuit can perform the checking for switching between the signal generation circuit and the bypass circuit actively or passively. For the active monitoring, the activation circuit can comprise, for example, an additional comparison circuit, for example containing a comparator or a controller and containing a sensor element, for example a current or voltage sensor. The comparison circuit can measure the power supply signal and evaluate it in accordance with the activation criterion.

Passive monitoring, on the other hand, can be provided, for example, by a switching element that is coupled to the power supply connection. The switching element may be able to be operated in a manner switchable under voltage control or current control, for example, depending on the power supply signal.

In the context of passive monitoring, there is provision in a further embodiment for the activation circuit to comprise at least one switching element, in particular an electronic switching element or a semiconductor switching element, for activating and deactivating the bypass circuit. This allows switching to be performed particularly easily, for example by making use of a typical switching characteristic of the switching element.

A switching element in the present instance means in particular an element for switching between at least two switching states, for example an activated or switched-on switching state and a deactivated or switched-off switching state. In the switched-on switching state, the switching element has substantially no electrical resistance. Electric current can therefore flow via the switching element substantially unhindered. In the switched-off switching state, the switching element has a substantially infinitely high electrical resistance, on the other hand. A flow of current via the switching element can therefore be prevented or blocked. The switching element may be implemented in particular as a transistor, for example as a bipolar or field-effect transistor, in particular as a MOSFET (metal oxide field-effect transistor) or as a thyristor or relay.

The switching element is connected to the power supply connection in such a way that the power supply signal can be used as a switching signal or control signal for putting the switching element into the switched-on or switched-off switching state. The aforementioned minimum limit value may be a switching value in accordance with the switching characteristic of the switching element.

According to another aspect, the invention also relates to a method for operating a signal processing device as was described previously. The method comprises the following operations: the power supply signal, which is delivered by the power supply unit and is able to be tapped off from the power supply connection, is first of all monitored in accordance with the predefined activation criterion. The result of the monitoring is then taken as a basis for performing one of the two measures that follow. Either, that is to say in particular if the result of the monitoring is negative, the control command delivered by the respective transmitting device via the respective transmitter connection is encoded into the communication-system-compliant control signal. The control signal is then delivered on the respective receiver connection. That is to say that the control signal can be tapped off from the receiver connection. Alternatively, that is to say if the result of the check is positive, the bypass circuit is activated. In the activated state of the bypass circuit, the trigger signal delivered by the transmitting device via the respective transmitter connection is delivered directly to the respective receiver connection by bypassing the signal generation circuit. The trigger signal is therefore able to be tapped off from the transmitter connection. The trigger signal differs from the control signal in this case.

For applications or application situations that can arise with the method, and which are not described explicitly here, there may be provision for the method to involve an error message and/or a prompt to input user feedback being output and/or a standard setting and/or a predetermined initial state being selected.

According to another aspect, the invention also relates to a communication system for an electrical network. The communication system comprises a signal processing device as was described previously. In addition, the communication system also comprises at least one signal line network, which has in particular at least one data line. The signal line network is designed to interconnect at least one transmitting device and at least one associated receiving device as were described previously in a communication-system-compliant topology in the electrical network. The communication system can therefore couple the terminals to one another in the network, specifically in a communication-system-compliant manner, that is to say depending on the type or style of the chosen communication system.

The signal line network may therefore be a physical transmission path for signal transmission in the network. To this end, the signal line network can comprise one or more lines or cables, for example the aforementioned data line. These can be used to transmit the control signal and the trigger signal to the respective terminal. A further line may be, for example, a power supply line that is used to route or transport the power supply signal in the communication network. If there is provision for two or more data lines, the topology indicates the interconnection or arrangement of the lines in the signal line network.

The signal processing device may be connected to the receiving device, for example by the receiver connection, via the signal line network, in particular a respective data line. The transmitting device may be connected directly to the transmitter connection, for example According to one embodiment, the communication system is in the form of a BUS system. In particular, it is a BUS system based on the LIN standard or the CAN standard or the FlexRay standard or the Ethernet standard. This results in the advantage that standardized networking of the terminals in the network can be provided for communication and signal transmission. The use of other BUS system standards is naturally also conceivable or implementable.

The function and layout of a BUS system for signal transmission in the electrical network is known per se. Known BUS systems are distinguished according to the style or type of communication standard, as were described previously, for example, or underlying communication protocols used. These are in particular standardized protocols or standards that prescribe inter alia the aforementioned signal encoding, topology and/or hierarchy in the network, for example.

In the present instance, preferably only such BUS systems as are short-circuit-proof based on or with respect to the operating potential, that is to say the power supply signal, are used for the communication system. That is to say that a BUS is used that, for example, has circuit for maximum current limiting and/or a protection circuit for shutting down in the event of a current maximum being exceeded in the network.

According to another aspect, the invention also relates to a transmitting device having a signal processing device as was described previously. The transmitter connection of the signal processing device is embodied as or in the form of a control connection of the transmitting device. The control connection allows the transmitting device to be coupled to the particular associated receiving device by a data line of a signal line network as was described previously, for example. The signal processing device is therefore integrated in the transmitting device as a component or element. Such chips or elements having an integrated communication unit are known per se. For example, there are controllers having an integrated LIN transceiver.

According to one embodiment, the transmitting device comprises an electrical energy storage unit that is designed to deliver or generate the trigger signal. The energy storage unit can therefore be understood as an emergency supply for the receiving device, in particular in the emergency state of the network. It may be connected in the transmitting device such that it automatically discharges to operate the receiving device in the emergency state of the network. As a result, the trigger signal is automatically output in the event of a fall in the supply. Alternatively, the transmitting device can comprise, for example, an activation circuit analogous to that of the signal processing device that undertakes activation or deactivation of the energy storage unit.

An energy store of the energy storage unit has a very much lower energy storage capacity than, for example, the aforementioned energy supplier of the power supply unit. By way of example, the storage capacity of the energy storage unit is just enough to generate the trigger signal. The storage capacity of the energy storage unit may be in the region of a few milliampere hours or milliwatt hours, for example. By contrast, the storage capacity of the energy storage apparatus may be in the range from a few watt hours or ampere hours to a few kiloampere hours or kilowatt hours or more. The energy storage apparatus is therefore designed for continuous operation of the network. By contrast, the energy storage unit is designed only for an emergency pulse, that is to say the trigger signal. The energy storage unit comprises a capacitor or a battery, for example, as an electrical energy store.

According to another aspect, the invention also relates to an electrical network comprising at least one transmitting device and at least one associated receiving device as were described previously. In addition, the electrical network also comprises a communication system as was mentioned previously. The transmitting device and the associated receiving device are connected to one another in the manner described for the aforementioned signal processing device and are coupled to one another by the communication system for the purpose of signal transmission. The electrical network may be, for example, a sensor network, house electrics, a computer network, a computer system, an electrical system of a vehicle or an automation device for an industrial installation, for example a robot for manufacturing vehicle parts.

An aspect of the invention also includes developments of the inventive method, of the transmitting device, of the communication system and of the electrical network as have already been described in the context of the developments of the inventive signal processing device.

For this reason, the relevant developments of the inventive method, of the transmitting device, of the communication system and of the electrical network are not described again here.

An aspect of the invention includes also comprises the combinations of features of the embodiments described. The invention thus also comprises implementations that each comprise a combination of the features of multiple instances of the embodiments described, provided that the embodiments were not described as mutually exclusive.

### BRIEF DESCRIPTION OF THE DRAWINGS

These and other aspects and advantages will become more apparent and more readily appreciated from the following description of the exemplary embodiments, taken in conjunction with the accompanying drawings of which:

Exemplary embodiments of the invention are described below. in this regard:

FIG. 1 shows a schematic representation of an electrical network for implementing an emergency supply of power to a receiving device via a LIN BUS according to an aspect of the invention,

FIG. 2 shows a schematic method flowchart for operating a signal processing device for signal encoding for the LIN BUS according to an aspect of the invention, and

FIG. 3 shows a schematic graph containing illustrative signal responses for various electrical signals that can be transmitted in the network according to an aspect of the invention.

### DETAILED DESCRIPTION

Reference will now be made in detail to the preferred embodiments, examples of which are illustrated in the accompanying drawings, wherein like reference numerals refer to like elements throughout.

The exemplary embodiments outlined below are preferred embodiments of the invention. In the exemplary embodiments, the described components of the embodiments each constitute individual features of the invention that should be considered independently of one another and that each also develop the invention independently of one another. Therefore, the disclosure is also intended to encompass combinations of the features of the embodiments other than the combinations presented. Furthermore, the embodiments described can also be supplemented by further features of the invention from among those already described.

In the figures, identical reference signs in each case denote functionally identical elements.

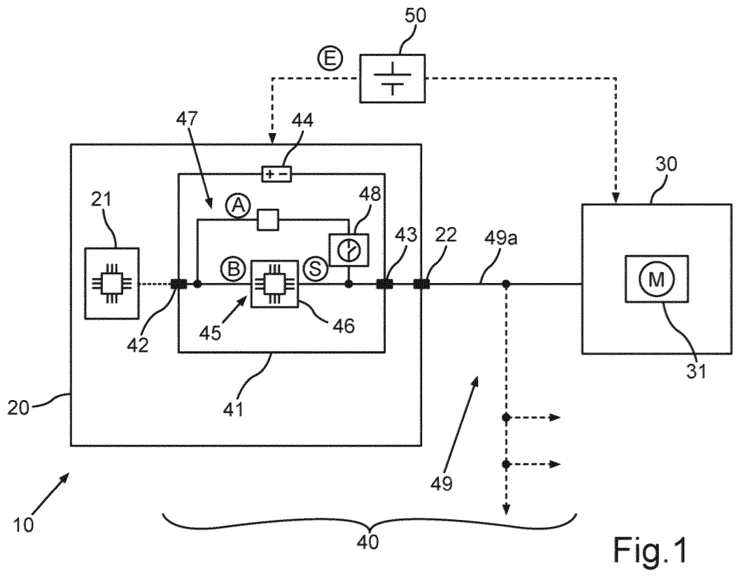

FIG. 1 shows a schematic representation of an electrical network 10. The electrical network may be encompassed, for example, by an electrical system of a vehicle, for example a motor vehicle. The motor vehicle may be, for example, a passenger vehicle or truck or passenger bus or motorcycle. By way of illustration, the network 10 shown in FIG. 1 forms an assembly of the vehicle for control, in particular for unlocking a vehicle door. The network 10 can be used in particular to implement electrical exterior handle operation of the vehicle door.

To this end, the network 10 comprises, by way of illustration, a transmitting device 20, an associated receiving device 30, a communication system 40 and a power supply unit 50.

The transmitting device 20 in the present instance is in the form of an electronic door controller (eTSG), for example. That is to say that the transmitting device 20 can be used to drive one or more receiving devices 30 associated with the vehicle door. To this end, the transmitting device 20 comprises a computing apparatus 21. The computing apparatus can comprise a microprocessor or microcontroller, for example. To control the particular associated receiving device 30, the transmitting device 20 can, in particular by the computing apparatus 21, generate control commands B. In the present exemplary embodiment, a control command may be “unlock door” or “lock door”, for instance.

A situation in which locking or unlocking is necessary can be determined by the computing apparatus 21 by evaluating sensor data from a vehicle sensor, which are delivered to the computing apparatus 21. Unlocking is required for example when a driver unlocks the vehicle using their vehicle key, for example. Conversely, locking is required for example when the driver locks the vehicle using the vehicle key. Alternatively, unlocking may also be necessary for example when the vehicle is involved in an accident or crash. This ensures that passengers can leave the crashed vehicle.

FIG. 1 shows a door unlocking apparatus as an example of a receiving device 30. Said door unlocking apparatus comprises, for example, a so-called Bowden cable that can be moved or adjusted for locking or unlocking. The Bowden cable can, in particular, be cast out for unlocking. To operate the Bowden cable, the receiving device 30 comprises a control element 31. The control element 31 is in the form of a servomotor for the Bowden cable, for example.

The control element 31 can be controlled or operated by driving it using the control command.

The receiving device 30 can comprise not only the control element 31 but also a driver circuit (not shown in FIG. 1), for example. The driver circuit can be employed in a manner known per se in order to apply the control command to the control element 31. In contrast to what is shown in FIG. 1, the network 10 can, for example, also comprise more than one receiving device, for example two or more receiving devices.

The power supply unit 50 is used to supply electric power to the components of the network 10. To this end, the power supply unit 50 can comprise, for example, an electrical energy supplier, such as a battery or a storage battery. In the present exemplary embodiment, the energy supplier may be a 12 V starter battery of the vehicle, for example.

The power supply unit 50 supplies power by delivering a power supply signal E to the components of the network 10. In the present instance, the power supply signal E may be, for example, a voltage signal having a rated voltage of 12 volts. This rated voltage is able to be tapped off or measured for example between a positive potential and a negative potential (ground potential) that are delivered by the energy supplier of the power supply unit 50.

The communication system 40 couples or connects the transmitting device 20 to the receiving device 30. The communication system 40 is employed in particular for communication or data transmission between the transmitting device 20 and the receiving device 30. In addition, the communication system 40 may provide a topology for the interconnection of the terminals with one another.

In the present instance, the communication system 40 is in the form of a so-called BUS system, for example, in particular in the form of a so-called LIN BUS (single-wire system). That is to say that the signal transmission in the network 10 and the topology of the terminal interconnection are provided based on the LIN standard, which is known per se.

The communication system 40 according to FIG. 1 comprises a signal processing device 41 and a signal line network 49. The signal line network 49 constitutes the physical transmission path or the wiring for signal transmission between the transmitting device 20 and the receiving device 30. To this end, the signal line network 49 comprises one or more data lines 49a. The data lines 49a are connected to one another in a network structure in a communication-system-compliant topology, in the present instance that is to say in a manner permissible for a LIN BUS. Moreover, the data lines 49a connect the terminals of the network 10 to one another. In the present exemplary embodiment, the transmitting device 20 is connected, for example by a control connection 22, to the receiving device 30, in particular by the control connection (not shown in FIG. 1) thereof, via a data line 49a.

The signal processing device 41 forms an adapter circuit or connection circuit for the transmitting device 20. In the present exemplary embodiment, the signal processing device 41 is an integral part of the transmitting device 20. That is to say that the components of the signal processing device 41 are completely integrated in the structure of the transmitting device 20.

For example, the signal processing device 41 and the computing apparatus 21 can have a common power supply connection 44 in order to receive the power supply signal E.

To incorporate the transmitting device 20, the signal processing device 41 is connected by a transmitter connection 42 to the computing apparatus 21. The transmitter connection 42 therefore forms an electrical contact with the transmitting device 20. A receiver connection 43 connects the signal processing device 41 to the control connection 22 of the transmitting device 20. The signal processing device 41 is therefore coupled to the receiving device 30 via the receiver connection 43.

The signal processing device 41 has two functions in the present instance: firstly, it is intended to be used as a translator for translating the control command B delivered by the computing apparatus 21 into a communication-system-compliant control signal S (communication function). That is to say that the control command is taken into a signal form that complies with the respective communication standard, in the present instance the LIN standard. This ensures that for example the correct receiving device is driven or the transmitting and receiving devices are synchronized for data transmission. The second function is to transmit electric power for at least briefly operating the receiving device 30 on demand (emergency operation function).

To perform the communication function, the signal processing device comprises a signal generation circuit 45. By way of example, the signal generation circuit 45 comprises a (signal processing) controller 46, which in the present instance may be in the form of a so-called LIN transceiver, for example. The signal generation circuit 45 is connected at one end to the transmitter connection 42 and at the other end to the receiver connection 43.

The controller 46 is designed to use the power supply signal E to encode the control command B delivered by the transmitting device 20 via the transmitter connection 42 into the communication-system-compliant control signal S. The control signal S is then delivered on the receiver connection 43 for transmission to the receiving device 30. The encoding follows the rules or standardizations that are specified in the LIN standard.

The receiving device 30 can receive the control signal S and decode it by the driver circuit, for example, in order to obtain the control command B. Said control command can then be used to drive the control element 31.

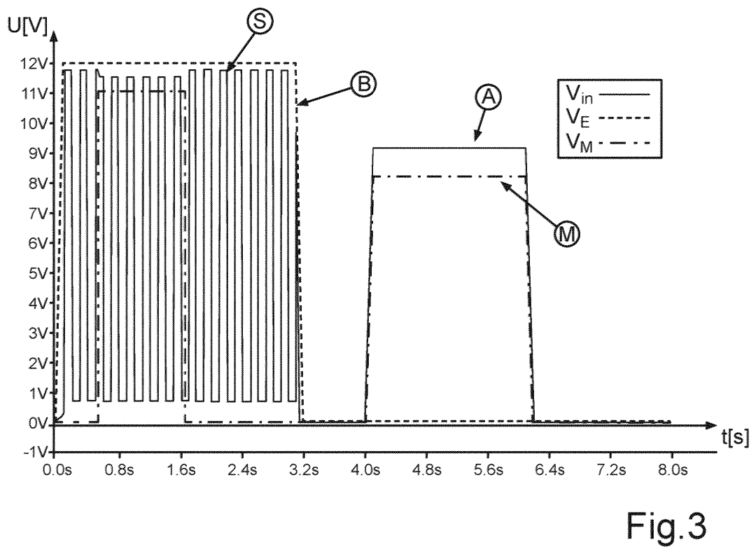

The control signal S is an information signal or data signal. That is to say that it transports no electric power for supplying power to the receiving device 30. In the present instance, the control signal S is in particular a digital signal that alternates between the voltage levels “high” and “low” in a predefined pulse pattern. The “high” level is predefined by the positive potential of the power supply signal E, for example. The “low” state, on the other hand, is predefined by the ground potential of the power supply signal E (see also FIG. 3).

To implement the emergency operation function, the signal processing device 41 also comprises a bypass circuit 47. The bypass circuit 47 bypasses or circumvents the signal generation circuit 45, in particular the controller 46. To this end, the bypass circuit 47 in the exemplary embodiment in FIG. 1 is connected to the transmitter connection 42 and the receiver connection 43 in electrical parallel with the signal generation circuit 45. The bypass circuit 47 comprises in particular no additional controller, that is to say in particular no active electrical components that need the supply signal E to operate. The bypass circuit 47 preferably comprises no more than passive electrical elements, for example resistors or diodes, that can be used for signal adaptation.

The bypass circuit 47 can therefore be used, in the activated state thereof, to deliver or transmit a trigger signal, which is delivered by the transmitting device 20, in particular the computing apparatus 21, via the transmitter connection 42, directly to the receiver connection 43 by bypassing the signal generation circuit 45. The trigger signal A differs in its signal type from the control signal S. For example, the trigger signal A is a supply or power signal. The trigger signal A is therefore in particular not a signal encoded in a communication-system-compliant manner.

The trigger signal A can also be referred to as a driver signal and drives or supplies the actuator system of the receiving device 30 with electric power. The trigger signal A is configured such that application to the control element 31 allows the receiving device 30 to be put into an emergency state by the trigger signal A. The emergency state may be a defined state to which the receiving device 30 is set when the network 10 is in an emergency state. The emergency state can arise, for example, in the event of a fall in the supply signal E, that is to say a loss of power, for example. It arises in the vehicle, for example, when the vehicle is involved in an accident that requires emergency shutdown of the battery, that is to say the power supply unit 50.

To generate the trigger signal A, the transmitting device preferably comprises an energy storage unit that can be used for emergency supply. That is to say that the energy storage unit can have an energy storage capacity of a few milliwatt hours, for example, which is just or no more than enough to deliver the trigger signal A. The energy storage unit can be charged by the power supply signal E, for example, during normal operation of the power supply unit 50. To this end, the energy storage unit can comprise, for example, an electrical buffer store, for example a battery or an electrical capacitor.

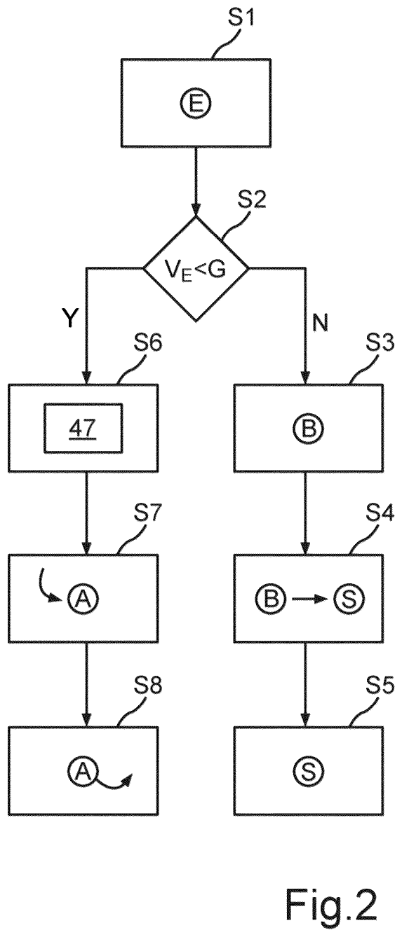

To switch between the communication function and the emergency operation function, the signal processing device 41 also comprises an activation circuit 48. The activation circuit 48 is designed to monitor the power supply signal E in accordance with a predefined activation criterion and to take the result of the monitoring as a basis for having the bypass circuit 47 activated or deactivated. The monitoring of the power supply signal A is described in more detail later in the context of FIG. 2.

To implement the switching function, the activation circuit 48 in the present instance comprises a switching element, in particular a semiconductor switch. Said semiconductor switch is connected between the bypass circuit 47 and the signal generation circuit 45, and so these are coupled via the semiconductor switch. The switching element may be in the form of a field-effect transistor, for example, in particular in the form of a MOSFET (metal oxide field-effect transistor). To activate the bypass circuit 47, the switching element can be taken into a switched-on switching state and therefore connected in an electrically conducting manner. For deactivation, on the other hand, the switching element can be taken into a switched-off switching state, and therefore connected in an electrically insulating manner.

For switching, that is to say activating or deactivating the bypass circuit 47, use is preferably made of the switching characteristic of the switching element. This allows the monitoring to be performed passively, and there is also no need for active components to be present in the activation circuit 48. In the specific embodiment as a MOSFET, the interconnection to provide the switching function may be implemented as follows, for example: the MOSFET can be connected by a gate-source connection, for example, to the power supply connection. On the other hand, a drain-source connection can connect the MOSFET to a line that connects the bypass circuit 47 to the signal generation circuit 45. The gate-source connection forms the control connection of the MOSFET. Therefore, depending on what value the power supply signal E has, the MOSFET can be either switched on or switched off. For example, the MOSFET is connected (switched on) when the supply signal E falls, that is to say there is the loss of power. Otherwise, the MOSFET remains in the switched-off state and the bypass circuit 47 is deactivated.

The conditions or prerequisites under which the communication function and the emergency operation function of the communication system 40 or of the signal processing device 41 are used are described once again in more detail below with reference to FIG. 2. FIG. 2 shows a schematic method flowchart for a method for operating the signal processing device 41.

In operation S1, the power supply signal E is first of all received or acquired by the activation circuit 48 via the power supply connection 44. That is to say that the power supply signal E can drop across the gate-source connection of the MOSFET, for example. In operation S2, the power supply signal E is evaluated by the activation circuit 48. This involves checking whether the power supply signal E, in accordance with the aforementioned activation criterion, has a response that is associated with the emergency state of the network 10. Specifically, this check may be implemented as a result of a present value of the power supply signal E, that is to say for example a voltage value, being compared with a predefined minimum limit value. The minimum limit value is a limit value for the supply signal E that symbolizes the emergency state. In the network 10 with the 12-volt rated voltage shown in FIG. 1, the minimum limit value G may be approximately 3 volts, for example. The minimum limit value G corresponds, for example, to the voltage value at which the switching element switches, as described previously.

If the check in operation S2 is negative (N), that is to say that the result of the check is that the supply signal value is above the minimum limit value G (greater than or equal to G), the method is continued in operation S3. In this case, the bypass circuit 47 remains deactivated because the switching element is in the switched-off switching state. The signal generation circuit 45 is therefore used for signal transmission. The signal processing device 41 performs the communication function. That is to say the control command B is received via the transmitter connection 42.

Next, in operation S4, the control command is encoded by the controller 46 into the communication-system-compliant control signal S. In operation S5, the control signal S is finally delivered to the receiver connection 43 for transmission to the receiving device 30 via the data line 49a.

If, on the other hand, the check in operation S2 is positive (Y), that is to say the supply signal value is below the limit value G (less than G), the method is continued in operation S6. In operation S6, the switching element is switched, on the basis of the switching characteristic thereof, to the switched-on switching state. This activates the bypass circuit 47. The emergency operation function is implemented. As the power supply unit 50 cannot or can no longer deliver enough electric power in the form of the power supply signal E to supply power, the trigger signal A is received via the transmitter connection 42 in operation S7. Said trigger signal is delivered directly to the output connection, in operation S8, by the activated bypass circuit 47 by bypassing the controller 46. Discharge of the energy storage unit to deliver the trigger signal A is the inevitable result in the network 10, to which the receiving device 30 is connected as a load.

FIG. 3 shows by way of illustration the possible signal response of the various signals in the network 10 firstly during performance of the communication function and secondly during performance of the emergency operation function of the signal processing device 41. The signals are shown as voltage signals U(V) over time t[s] in a voltage-time graph. The signal responses shown in FIG. 3 are an input voltage Vin, a motor voltage VM and a supply voltage VE. The input voltage Vin is able to be tapped off from the transmitter connection 42 as an input signal for the receiving device 30 and therefore represents the control signal S and the trigger signal A. The power supply voltage VE is able to be tapped off from the power supply connection 44 and therefore represents the power supply signal E. The motor voltage VM is able to be tapped off from the servomotor for the Bowden cable, for example, that is to say from the control element 31, during the operation thereof.

As shown in the graph in FIG. 3, the power supply voltage VE initially has a value of approximately 12 volts (positive potential). It is above the minimum limit value. The input voltage Vin has the typical response of a digital signal or AC signal. It alternates to and fro, for example at regular intervals, between the “high” state (positive potential) and the “low” state (negative potential). This response of the input voltage represents the control signal S. The control command B encoded in the control signal can be used to adjust the servomotor, as shown by the approximately one-second pulse of the motor voltage VM in the graph. For example, the Bowden cable can be operated in order to lock the vehicle door.

After around three seconds, there is a loss of power, and the power supply voltage VE goes down to substantially zero volt (ground potential). The minimum limit value of, by way of illustration, 3 V is not reached. The network 10 is in the emergency state. The fall in the power supply voltage VE also results in the input signal Vin changing to approximately zero volt.

Shortly after the loss of power, it can be seen that the input voltage Vin has a single voltage pulse. This pulse is maintained at a level of approximately 9 V over a period of approximately 2.3 seconds, for example. The voltage pulse represents the trigger signal A. The motor voltage VM substantially succeeds the input voltage Vin, said input voltage only maintaining a level of approximately 8 V over the period of the voltage pulse, for example. This pulse pattern in accordance with the trigger signal A is a specific signal that operates or supplies power to the servomotor such that the default setting is selected, that is to say the Bowden cable is cast out, for example. The vehicle door is unlocked.

All in all, the exemplary embodiments show how an emergency supply of power to a receiving device via a LIN line can be implemented by a LIN BUS.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-10. (canceled)

11. A signal processing device of a communication system to process electrical signals to be transmitted, in an electrical network, between at least one transmitting device and at least one receiving device using the communication system, the signal processing device comprising:
a transmitter connection to be coupled to the at least one transmitting device and a receiver connection to be coupled to the at least one receiving device,
a power supply connection to be coupled to a power supply unit for supplying electric power for the electrical network,
a signal generation circuit having at least one signal generation controller that is designed to encode a control command delivered by the at least one transmitting device via the transmitter connection into a communication-system-compliant control signal and to deliver the communication-system-compliant control signal on the receiver connection,
a bypass circuit, while in an activated state, to deliver a trigger signal, which is delivered by the at least one transmitting device via the transmitter connection and differs in a signal type from the communication-system-compliant control signal, directly to the receiver connection by bypassing the signal generation circuit, and
an activation circuit to monitor a power supply signal, which is delivered by the power supply unit and is able to be tapped off from the power supply connection, in accordance with a predefined activation criterion, and to take a result of the power supply signal monitored as a basis for activating the bypass circuit.

12. The signal processing device as claimed in claim 11, wherein the activation circuit is designed to check, in accordance with the predefined activation criterion, whether the power supply signal, in accordance with a check condition, has a response that is associated with a predefined emergency state of the electrical network, and to activate the bypass circuit based on the check being positive.

13. The signal processing device as claimed in claim 12, wherein the activation circuit is designed to check, in accordance with the check condition, whether the power supply signal currently has a value that is below a predefined minimum limit value that indicates that the predefined emergency state exists, and to activate the bypass circuit based on the check being positive.

14. The signal processing device as claimed in claim 11, wherein the activation circuit comprises at least one switching element, and wherein the at least one switching element is an electronic switching element or a semiconductor switching element, for activating the bypass circuit.

15. The signal processing device as claimed in claim 12, wherein the activation circuit comprises at least one switching element, and wherein the at least one switching element is an electronic switching element or a semiconductor switching element, for activating the bypass circuit.

16. The signal processing device as claimed in claim 13, wherein the activation circuit comprises at least one switching element, and wherein the at least one switching element is an electronic switching element or a semiconductor switching element, for activating the bypass circuit.

17. A method of operating the signal processing device as claimed in claim 11, the method comprising:
monitoring the power supply signal, which is delivered by the power supply unit and is able to be tapped off from the power supply connection, in accordance with the predefined activation criterion, and taking a result of the monitoring as a basis for one of:
encoding a control command delivered by the at least one transmitting device via the transmitter connection into the communication-system-compliant control signal and delivering the communication-system-compliant control signal on the receiver connection, or
activating the bypass circuit and, in the activated state of the bypass circuit, delivering the trigger signal, which is delivered by the at least one transmitting device via the transmitter connection and differs from the communication-system-compliant control signal, directly to the receiver connection by bypassing the signal generation circuit.

18. A communication system, comprising:
the signal processing device as claimed in claim 11, and at least one signal line network that is designed to interconnect the at least one transmitting device and the at least one receiving device in a communication-system-compliant topology in the electrical network.

19. The communication system as claimed in claim 18, wherein the communication system forms a BUS system based on the LIN standard or the CAN standard or the FlexRay standard or the Ethernet standard.

20. A transmitting device having the signal processing device as claimed in claim 11,
wherein the transmitter connection of the signal processing device is embodied as a control connection of the at least one transmitting device, the at least one transmitting device being able to be coupled to the at least one receiving device via the control connection by a data line of a signal line network.

21. The transmitting device as claimed in claim 20, wherein the transmitting device comprises an electrical energy storage unit that is designed to deliver the trigger signal.

22. The electrical network comprising the at least one transmitting device, the at least one receiving device and the communication system as claimed in claim 18.

23. The electrical network comprising the at least one transmitting device, the at least one receiving device and the communication system as claimed in claim 19.
